(19) United States
(12) Patent Application Publication
(10) Pub. No.: US 2026/0173463 A1
(43) Pub. Date: Jun. 18, 2026

(54) SEMICONDUCTOR DEVICE AND MANUFACTURING METHOD THEREOF

(71) Applicant: Hon Young Semiconductor Corporation, Hsinchu City (TW)

(72) Inventor: Chen-Hao HSU, Hsinchu City (TW)

(21) Appl. No.: 19/050,068

(22) Filed: Feb. 10, 2025

(30) Foreign Application Priority Data
Dec. 13, 2024 (TW) 113148543

(51) Int. Cl. H10D 62/10; H10D 30/01; H10D 30/66

(52) U.S. Cl. CPC H10D 62/111; H10D 30/0297; H10D 30/668

(57) ABSTRACT

A semiconductor device includes a substrate, an epitaxial layer and a gate structure. The epitaxial layer is over the substrate. The epitaxial layer includes a drift region, a plurality of doped pillars, a well region, a source region, and a channel doped region. The doped pillars are in the drift region. The well region is over the drift region. The source region is over the well region. The channel doped region is under the source region and in the well region. The substrate, the drift region, the source region, and the channel doped region have a first conductivity type. The well region and the doped pillars have a second conductivity type different from the first conductivity type. A doping concentration of the channel doped region is lower than a doping concentration of the source region. The gate structure is embedded in the epitaxial layer.

### CROSS-REFERENCE TO RELATED APPLICATION

This application claims priority to Taiwan Application Serial Number 113148543, filed Dec. 13, 2024, which is herein incorporated by reference in its entirety.

### BACKGROUND

### Technical Field

Some embodiments of the present disclosure relate to a semiconductor device and a manufacturing method thereof.

### Description of Related Art

With the development of semiconductor technology, the needs for faster processing systems and higher performance continue to grow. To meet these needs, in the semiconductor industry, the current of a transistor device such as a metal oxide semiconductor field effect transistor (MOSFET) is continuously increased to increase the power conversion efficiency. However, in some semiconductor devices that need to be used in switching power supply systems such as a SMPS (switching mode power supply), it is still more necessary to provide its switching rate to achieve better performance.

### SUMMARY

Some embodiments of the present disclosure comprise a semiconductor device comprising a substrate, an epitaxial layer and a gate structure. The epitaxial layer is over the substrate, wherein the epitaxial layer comprises a drift layer, a plurality of doped pillars, a well region, a source region, and a channel doped region. The plurality of doped pillars are in the drift region. The well region is over the drift region. The source region is over the well region. The channel doped region is under the source region and in the well region, wherein the substrate, the drift region, the source region, and the channel doped region have a first conductivity type, the well region and the plurality of doped pillars have a second conductivity type different from the first conductivity type, and a doping concentration of the channel doped region is lower than a doping concentration of the source region. The gate structure is embedded in the epitaxial layer.

In some embodiments, the channel doped region is in contact with the gate structure.

In some embodiments, a bottom of the channel doped region is higher than a bottom of the well region.

In some embodiments, the plurality of doped pillars are arranged in a direction, and a width of the channel doped region in said direction is less than a width of the source region in said direction.

In some embodiments, the epitaxial layer further comprises a JFET region between the well region and the drift region, the JFET region having the first conductivity type.

In some embodiments, one of the plurality of doped pillars is directly below the gate structure.

In some embodiments, the gate structure comprises a gate dielectric layer and a gate layer. The gate dielectric layer is in contact with the channel doped region. The gate layer is surrounded by the gate dielectric layer.

In some embodiments, the gate structure comprises a gate dielectric layer and two gate layers. The gate dielectric layer is in contact with the channel doped region. The two gate layers are surrounded by the gate dielectric layer and separated from each other by the gate dielectric layer.

Some embodiments of the present disclosure comprise a manufacturing method of a semiconductor device, comprising: forming an epitaxial layer over a substrate, wherein the epitaxial layer has a first conductivity type; forming a trench in the epitaxial layer; forming a plurality of doped pillars in the epitaxial layer, wherein the doped pillars have a second conductivity type different from the first conductivity type; forming a well region, a channel doped region and a source region on one side of the trench, wherein the source region is over the well region, and the channel doped region is under the source region and in the well region, the source region and the channel doped region have the first conductivity type, and the well region has the second conductivity type, and a doping concentration of the channel doped region is lower than a doping concentration of the source region; and forming a gate structure in the trench.

In some embodiments, the channel doped region is in contact with the gate structure.

### BRIEF DESCRIPTION OF THE DRAWINGS

FIGS. 1-5 illustrate a cross-sectional view of forming a semiconductor device in some embodiments of the present disclosure; and

FIG. 6 illustrates a cross-sectional view of a semiconductor device according to some other embodiments of the present disclosure.

### DETAILED DESCRIPTION

Some embodiments of the present disclosure relate to a semiconductor device used in a switching mode power supply system (SMPS). The semiconductor device in the present disclosure has channel doped regions on both sides of a gate structure, which can be used to increase a switch-on speed and a switching rate of the semiconductor device.

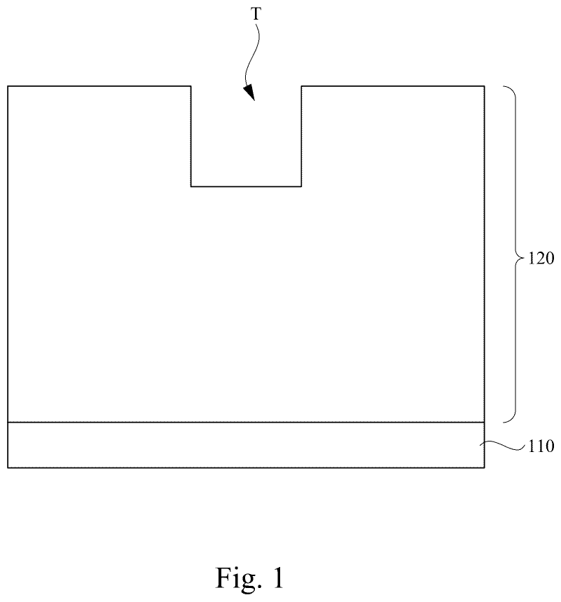

FIGS. 1-5 illustrate a cross-sectional view of forming a semiconductor device in some embodiments of the present disclosure. Referring to FIG. 1, an epitaxial layer 120 is formed over a substrate 110. Then, a trench T is formed in the epitaxial layer 120. The substrate 110 and the epitaxial layer 120 may be made of a semiconductor material such as silicon, silicon carbide, an analog, or a combination thereof. The substrate 110 and the epitaxial layer 120 may have a first conductivity type, the substrate 110 may be a heavily doped region, the epitaxial layer 120 may be a lightly doped region, and a doping concentration of the epitaxial layer 120 is lower than a doping concentration of the substrate 110. In some embodiments, the substrate 110 may be an N-type heavily doped substrate, and the epitaxial layer 120 may be an N-type lightly doped region. In some embodiments, the doped regions of the first conductivity type may include an N-type dopant such as nitrogen, arsenic, or phosphorus.

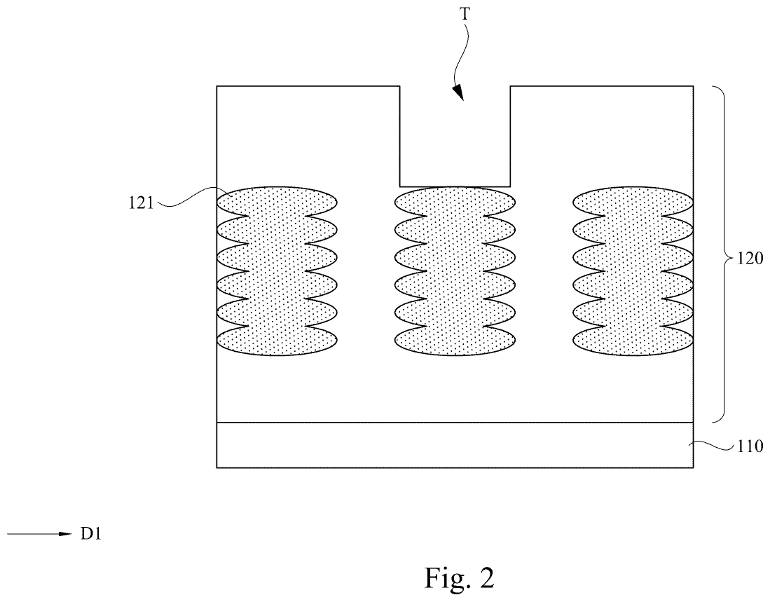

Referring to FIG. 2, a plurality of doped pillars 121 are formed in the epitaxial layer 120. The doped pillars 121 can be formed by performing an ion implantation process on the epitaxial layer 120. The doped pillars 121 are arranged in a direction D1, and one of the doped pillars 121 is located directly below the trench T. A top of the doped pillar 121 is not higher than a bottom of the trench T. The doped pillars 121 have a second conductivity type different from the first conductivity type. In some embodiments, the doped pillar 121 may be a P-shaped doped region. In some embodiments, the doped regions of the second conductivity type may include a P-type dopant such as boron, aluminum, or gallium. The doped pillars 121 in the epitaxial layer 120 have a different conductivity type from the epitaxial layer 120 that is not occupied by the doped pillars 121. The epitaxial layers having different conductivity types are alternately arranged in the direction D1, so that a super junction structure can be formed during a subsequent operation of the semiconductor device to reduce a switch-on resistance of the semiconductor device. It should be noted that although the present disclosure shows that the doped pillars 121 are formed by performing an ion implantation process, the doped pillars 121 in the present disclosure are not limited to being formed in this manner. In some embodiments, the doped pillars 121 in the present disclosure may also be formed by etching the epitaxial layer 120 to form trenches in the epitaxial layer 120 for accommodating the doped pillars 121, and then filling the trenches with a suitable semiconductor material.

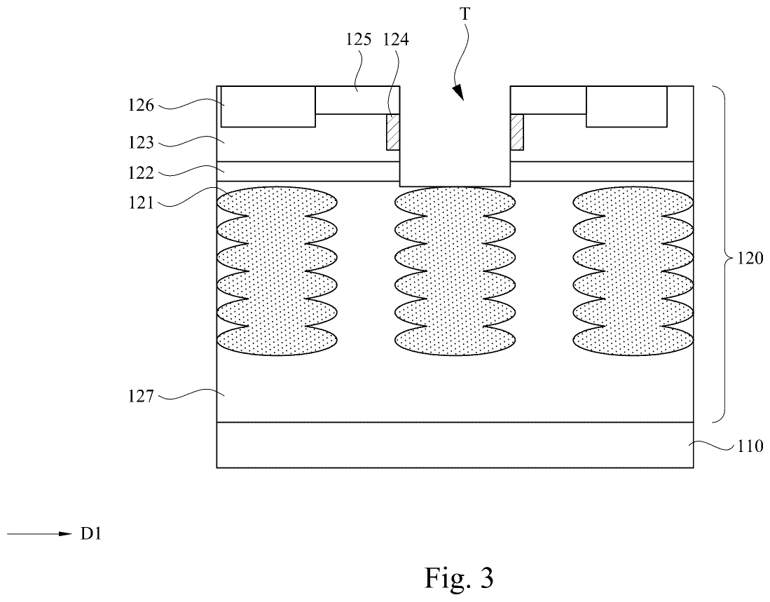

Referring to FIG. 3, a JFET (junction field-effect transistor) region 122, a well region 123, a channel doped region 124, a source region 125 and a body contact region 126 are formed on one side of the trench T, and the remaining portion is a drift region 127. The source region 125 and the body contact region 126 are over the well region 123, the channel doped region 124 is under the source region 125 and in the well region 123, the JFET region 122 is between the well region 123 and the drift region 127, and the drift region 127 is under the well region 123. The JFET region 122, the channel doped region 124, the source region 125 and the drift region 127 have the first conductivity type, and the well region 123 and the body contact region 126 have the second conductivity type. A doping concentration of the channel doped region 124 is lower than a doping concentration of the source region 125, the doping concentration of the source region 125 is higher than a doping concentration of the JFET region 122, and a doping concentration of the drift region 127 is lower than the doping concentration of the JFET region 122. A doping concentration of the well region 123 is lower than a doping concentration of the body contact region 126. After the JFET region 122, the well region 123, the channel doped region 124, the source region 125, the body contact region 126 and the drift region 127 are formed, a side wall of the trench T exposes the JFET region 122, the channel doped region 124 and the source region 125.

In some embodiments, a bottom of the channel doped region 124 is higher than a bottom of the well region 123. In some embodiments, a width of the channel doped region 124 in the direction D1 is less than a width of the source region 125 in the direction D1. The channel doped region 124 can be configured to improve switching rates of components switched on and off in the subsequent operation of the semiconductor device.

It should be noted that the present disclosure does not limit the order of formation of the different doped regions and the trench, so the order of formation of the different doped regions and the trench is not limited to that shown in FIGS. 1-3. For example, the drift region 127, the doped pillars 121, the JFET region 122, the well region 123, the source region 125 and the body contact region 126 can be formed in the epitaxial layer 120 first, and then the trench T is formed in the epitaxial layer 120. Next, the channel doped regions 124 are formed on both sides of the trench T.

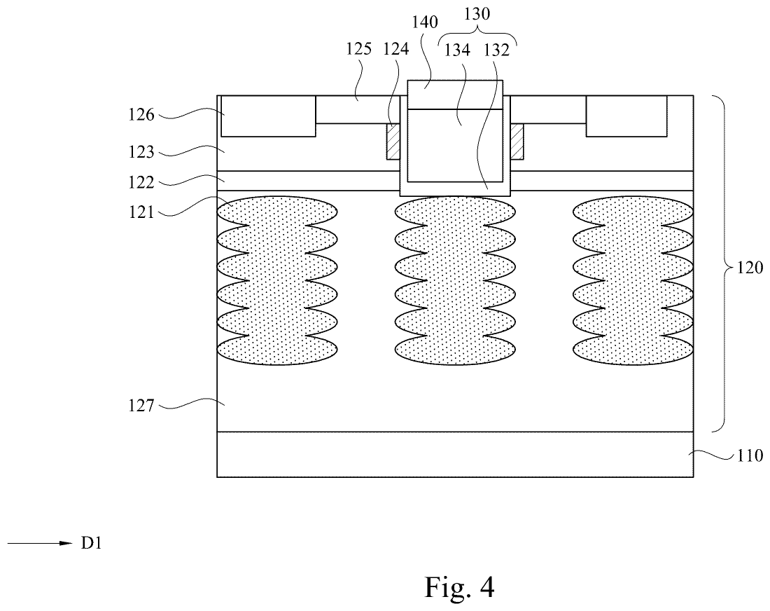

Referring to FIG. 4, a gate structure 130 is formed in the trench T. In particular, a gate dielectric layer 132 lining the trench T may be formed in the trench first, and then a gate layer 134 is formed in the trench T. Next, excess portions of the gate dielectric layer 132 and the gate layer 134 outside the trench T are removed. The gate dielectric layer 132 and the gate layer 134 constitute the gate structure 130. Since a side wall of the trench T exposes the JFET region 122, the channel doped region 124 and the source region 125, the resulting gate structure 130 is also in contact with the JFET region 122, the channel doped region 124, and the source region 125. In some embodiments, a thickness of the gate dielectric layer 132 along a bottom of the gate layer 134 is greater than a thickness of the gate dielectric layer 132 along a side wall of the gate layer 134. In some embodiments, the gate dielectric layer 132 may be made of silicon oxide, silicon nitride, or an analog. The gate layer 134 may be made of a semiconductor material or a conductor material, such as polycrystalline silicon or a metal.

After the gate structure 130 is formed, a gate electrode 140 is formed on the gate layer 134 of the gate structure 130. In some embodiments, the gate electrode 140 is formed from a conductor such as a metal.

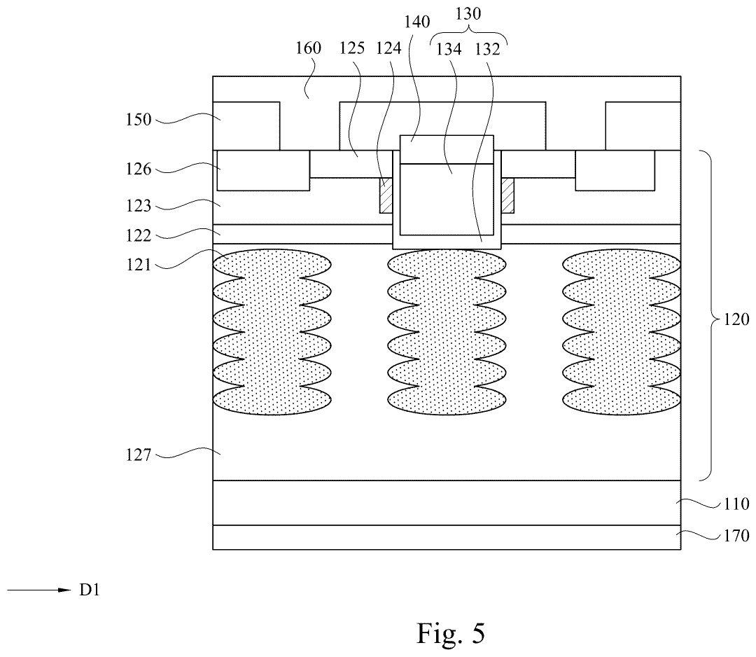

Referring to FIG. 5, a dielectric layer 150 is formed on the epitaxial layer 120 and the gate structure 130. Then, the trench exposing the source region 125 and the body contact region 126 is formed in the dielectric layer 150. Next, a source electrode 160 in contact with the source region 125 and the body contact region 126 is formed in the trench, and a drain electrode 170 is formed under the substrate 110. The source electrode 160 is electrically isolated from the gate electrode 140 by the dielectric layer 150. In some embodiments, the dielectric layer 150 may be made of silicon oxide, silicon nitride, or an analog. In some embodiments, the source electrode 160 and the drain electrode 170 may be made of a conductive material such as a metal.

The resulting semiconductor device is shown in FIG. 5. The semiconductor device includes a substrate 110, an epitaxial layer 120 and a gate structure 130. The epitaxial layer 120 is over the substrate 110, wherein the epitaxial layer 120 includes a drift region 127, a plurality of doped pillar 121, a well region 123, a source region 125, a channel doped region 124, a JFET region 122 and a body contact region 126. The doped pillars 121 are in the drift region 127. The well region 123 is over the drift region 127. The source region 125 is over the well region 123. The channel doped region 124 is under the source region 125 and in the well region 123, wherein the substrate 110, the drift region 127, the source region 125, the channel doped region 124 and the JFET region 122 have a first conductivity type, the well region 123, the doped pillars 121 and the body contact region 126 have a second conductivity type different from the first conductivity type, a doping concentration of the channel doped region 124 is lower than a doping concentration of the source region 125, the doping concentration of the source region 125 is higher than a doping concentration of the JFET region 122, and a doping concentration of the drift region 127 is lower than the doping concentration of the JFET region 122. A doping concentration of the well region 123 is lower than a doping concentration of the body contact region 126.

The gate structure 130 is embedded in the epitaxial layer 120. The gate structure 130 includes a gate dielectric layer 132 and a gate layer 134. The gate dielectric layer 132 is in contact with the channel doped region 124. The gate layer 134 is surrounded by the gate dielectric layer 132.

The channel doped region 124 of the semiconductor device in the present disclosure can be used to improve a switching rate of the semiconductor device switched on and off. In particular, the switching rate of the semiconductor device switched on and off can be determined by charging rates of a gate-to-source capacitor Cgs and a gate-to-drain capacitor Cgd, and the smaller the amount of charge required to charge the Cgs and the Cgd is, the higher a switch-on speed of the semiconductor device is. When a gate voltage of the semiconductor device of the present disclosure is 0, the channel doped regions 124 on both sides of the gate structure 130 are fully depleted regions, so the channel doped regions 124 can be used to reduce the amount of charge required to charge the Cgs and the Cgd, thereby improving the switch-on speed and the switching rate of the semiconductor device.

In addition, the doped pillars 121 of the present disclosure are configured to reduce the switch-on resistance of the semiconductor device. Specifically, in some embodiments, one of the doped pillars 121 is directly below the gate structure 130, and one of the doped pillars 121 is directly below the well region 123. The doped pillars 121 and the drift region 127 have different conductivity types and are alternately arranged along the direction D1, so that a super junction structure can be formed during a subsequent operation of the semiconductor device to reduce the switch-on resistance of the semiconductor device.

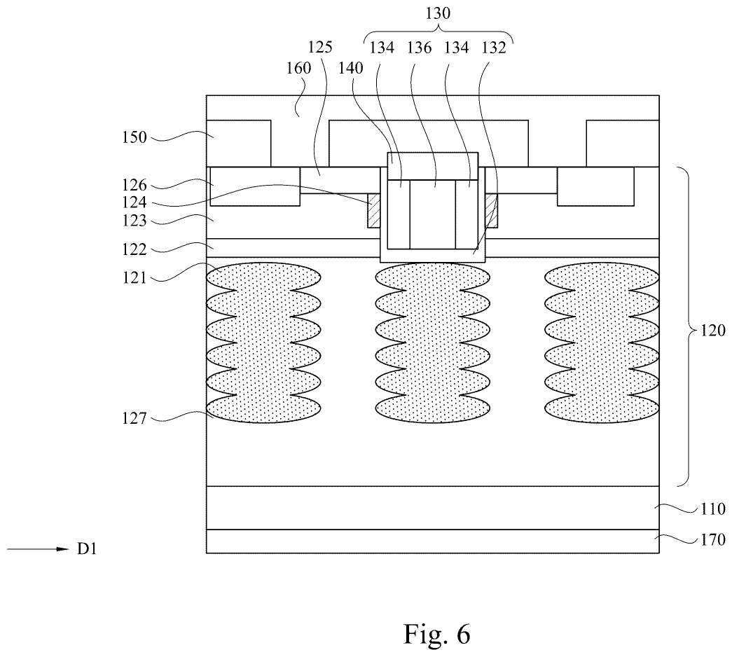

FIG. 6 illustrates a cross-sectional view of a semiconductor device according to some other embodiments of the present disclosure. The semiconductor device in FIG. 6 is similar to the semiconductor device in FIG. 5, except that a gate structure 130 in FIG. 6 is a split gate structure. The gate structure 130 includes a gate dielectric layer 132 and two gate layers 134. The gate dielectric layer 132 is in contact with the channel doped region 124. The gate layers 134 are surrounded by the gate dielectric layer 132, and the gate layers 134 are separated from each other by the dielectric layer 136. In some embodiments, the gate layers 134 are arranged in the same direction as the doped pillars 121 (e.g., both along the direction D1). In some embodiments, the gate dielectric layer 132 may be made of silicon oxide, silicon nitride, or an analog. The gate layers 134 may be made of a semiconductor material or a conductor material, such as polycrystalline silicon or a metal. In some embodiments, both of the gate layers 134 are made of a same material.

A manufacturing method of the semiconductor device in FIG. 6 is also similar to a manufacturing method of the semiconductor device in FIGS. 1-5. A difference is that after the gate dielectric layer 132 is formed, a thicker conformal conductor layer can first be formed in the trench T. Then, a horizontal portion of the conformal conductor layer is removed, and only a vertical conductor layer along the side wall of the trench T is left. The two gate layers 134 are thus formed along the side walls of the trench T. Next, the dielectric layer 136 is filled in the trench T to fill the remaining portion of the trench T. Finally, excess portions of the gate dielectric layer 132 and the dielectric layer 136 outside the trench T are removed. The gate structure 130 of the semiconductor device in FIG. 6 is thus formed. When the gate structure 130 is a split gate structure, an overlap region between the gate layer 134 of the gate structure 130 and the drain electrode can be reduced, so the gate-to-drain capacitor Cgd can be reduced. In this way, the amount of charge required to charge the Cgd can be reduced, thereby increasing the switch-on speed and the switching rate of the semiconductor device.

In summary, the semiconductor device of the present disclosure has the channel doped regions on both sides of the gate structure. The channel doped regions may be fully depleted regions when a gate voltage of the semiconductor device is 0, so the channel doped regions 124 can be used to reduce the amount of charge required to charge the gate-to-source capacitor Cgs and the gate-to-drain capacitor Cgd, thereby increasing the switch-on speed and the switching rate of the semiconductor device. In addition, the semiconductor device may further include the super junction structure and the split gate structure to further reduce the switch-on speed, the switching rate and the switch-on resistance of the semiconductor device.

The forgoing embodiments are merely a part rather than all of the embodiments of the present disclosure, and any equivalent change to the technical solution of the present disclosure made by a person of ordinary skill in the art by reading the specification of the present disclosure shall fall within the protection scope of the present invention.

What is claimed is:

1. A semiconductor device, comprising:
a substrate;
an epitaxial layer over the substrate, the epitaxial layer comprising:
a drift region;
a plurality of doped pillars in the drift region;
a well region over the drift region;
a source region over the well region; and
a channel doped region under the source region and in the well region, wherein the substrate, the drift region, the source region, and the channel doped region have a first conductivity type, the well region and the plurality of doped pillars have a second conductivity type different from the first conductivity type, and a doping concentration of the channel doped region is lower than a doping concentration of the source region; and
a gate structure embedded in the epitaxial layer.

2. The semiconductor device according to claim 1, wherein the channel doped region is in contact with the gate structure.

3. The semiconductor device according to claim 1, wherein a bottom of the channel doped region is higher than a bottom of the well region.

4. The semiconductor device according to claim 1, wherein the plurality of doped pillars are arranged in a direction, and a width of the channel doped region in said direction is less than a width of the source region in said direction.

5. The semiconductor device according to claim 1, wherein the epitaxial layer further comprises:
a JFET region between the well region and the drift region, the JFET region having the first conductivity type.

6. The semiconductor device according to claim 1, wherein one of the plurality of doped pillars is directly below the gate structure.

7. The semiconductor device according to claim 1, wherein the gate structure comprises:
a gate dielectric layer in contact with the channel doped region; and
a gate layer surrounded by the gate dielectric layer.

8. The semiconductor device according to claim 1, wherein the gate structure comprises:
a gate dielectric layer in contact with the channel doped region; and
two gate layers surrounded by the gate dielectric layer, and separated from each other by the gate dielectric layer.

9. The semiconductor device according to claim 8, wherein the two gate layers are arranged in the same direction as the plurality of doped pillars.

10. A manufacturing method of a semiconductor device, comprising:
forming an epitaxial layer over a substrate, wherein the epitaxial layer has a first conductivity type;
forming a trench in the epitaxial layer;
forming a plurality of doped pillars in the epitaxial layer, wherein the doped pillars have a second conductivity type different from the first conductivity type;
forming a well region, a channel doped region and a source region on one side of the trench, wherein the source region is over the well region, and the channel doped region is under the source region and in the well region, the source region and the channel doped region have the first conductivity type, and the well region has the second conductivity type, and a doping concentration of the channel doped region is lower than a doping concentration of the source region; and
forming a gate structure in the trench.

11. The manufacturing method according to claim 10, wherein the channel doped region is in contact with the gate structure.

12. The manufacturing method according to claim 10, wherein a side wall of the trench exposes the channel doped region after the trench is formed.

13. The manufacturing method according to claim 10, wherein a bottom of the channel doped region is higher than a bottom of the well region.

14. The manufacturing method according to claim 10, wherein forming the gate structure comprising:
forming a gate dielectric layer lining the trench and in contact with the gate dielectric layer; and
forming a gate layer in the trench and over the gate dielectric layer.

15. The manufacturing method according to claim 10, wherein forming the gate structure comprising:
forming a gate dielectric layer lining the trench and in contact with the gate dielectric layer;
forming two gate layers along sidewalls of the trench; and
filling a dielectric layer in the trench and separating the two gate layers.

16. The manufacturing method according to claim 15, wherein the two gate layers are arranged in the same direction as the doped pillars.

17. The manufacturing method according to claim 15, wherein the plurality of doped pillars are arranged in a direction, and a width of the channel doped region in said direction is less than a width of the source region in said direction.

18. The manufacturing method according to claim 10, further comprising:
forming a JFET region in the epitaxial layer, wherein the JFET region is below the well region and has the first conductivity type.

19. The manufacturing method according to claim 18, wherein the channel doped region is over the JFET region.

20. The manufacturing method according to claim 10, wherein one of the plurality of doped pillars is directly below the gate structure.
